(19) United States
(12) Patent Application Publication
(10) Pub. No.: US 2014/0266189 A1
(43) Pub. Date: Sep. 18, 2014

(54) RF SHIELD FOR USE IN A MAGNETIC RESONANCE SYSTEM

(71) Applicants: Rares Salomir, Ambilly (FR); Magalie Viallon, Lyon (FR); Lorena Petrusca, Villeurbanne (FR)

(72) Inventors: Rares Salomir, Ambilly (FR); Magalie Viallon, Lyon (FR); Lorena Petrusca, Villeurbanne (FR)

(21) Appl. No.: 13/836,033

(22) Filed: Mar. 15, 2013

(51) Int. Cl. G01R 33/422

(52) U.S. Cl. CPC G01R 33/422
USPC 324/307; 324/322

(57) ABSTRACT

An RF active device, immersed in liquid medium, for use in a magnetic resonance system is provided with an RF shield formed of electrically conductive material and having an interior cavity configured to receive the RF active device therein. The RF shield substantially precludes coupling between the active device, and any coupling medium that is employed, and the transmission and reception coils of the magnetic resonance system.

### BACKGROUND OF THE INVENTION

1. Field of the Invention

The present invention concerns a radio-frequency (RF) shield for an ultrasound transducer or other device immersed in a coupling medium, to be used inside a magnetic resonance imaging or spectroscopy system.

2. Description of the Prior Art

With the purpose of monitoring or for interventional procedures in an magnetic resonance imaging or spectroscopy system, various RF active devices are used inside the magnet bore, for instance: ultrasound transducer, accelerometer, magnetometer, mechanical actuator, optical or infrared camera.

When operating an ultrasound system such as a HIFU system or ultrasonography device, the ultrasound energy (ultrasound waves) must be transferred from the ultrasound transducer to the target body, such as a patient, via a suitable medium. It may also be advantageous for the medium to be a liquid that is capable of transporting heat away from the transducer or the body surface. Typically degassed water is used as such a medium. Examples of such ultrasound systems are HIFU systems, non-focused therapeutic ultrasound lithotripsy, diagnostic ultrasound, ultrasound arrangements that induce shear waves for magnetic resonance-based shear-wave elastography, and other comparable ultrasound systems.

When operating an optical or infrared camera, the respective portion of the light spectrum must be able to propagate and to reach the surface of the target body, such as a patient.

Several problems can occur when operating such an RF active device in conjunction with a magnetic resonance imaging or spectroscopy system, as is the case in a magnetic resonance guided HIFU (MRg HIFU) procedure.

One problem is that RF antennas that are used for transmission in the magnetic resonance system may couple to the liquid or to the immersed device (e.g. transducer) itself. Such coupling may damage the RF active device, due to the high RF transmission powers that are used in magnetic resonance. Thermal damage of the superficial layers of the active device or electric damage of the embedded components may occur. Additionally, there will likely be energy (power) absorbed by the liquid or by the transducer, so that the RF transmission power for the magnetic resonance system has to be correspondingly increased. Moreover, the presence of the immersed device (e.g. transducer) and the liquid may cause the magnetic resonance transmission coil to become detuned, resulting in reflections toward the amplifier that is connected to the coil, and again requiring a higher transmission power. Lastly, the dielectric effect of the medium may adversely reduce the field homogeneity of the RF transmission field, thereby causing artifacts in the resulting image. In magnetic resonance systems that employ very high fields, this dielectric effect may cause specific absorption great hot spots, thereby causing discomfort, or even injury, to the patient.

Another category of problems results from the radio-frequency antennas of the magnetic resonance system that are used for reception coupling to the liquid or the immersed device (e.g. transducer) itself. This coupling of the reception antenna, due to losses in the liquid or in the transducer, may cause the magnetic resonance reception coil to detect (receive) a higher level of thermal noise. Moreover, the reception coil may become detuned, resulting in a higher noise factor in the amplifier connected to the reception coil, and thus a reduced sensitivity to the useful magnetic resonance signal that is being simultaneously detected.

Additionally, the electrical RF active signal that is sent to the RF active device (composed of one or more fundamental frequencies, their harmonics, and other frequencies that may exist in an “unclean” signal) may couple into the reception coil, and any portion of this coupled-in signal that is then digitized in the processing of the received MR signal will cause artifacts in the reconstructed image. This “parasite” signal may also possibly cause switching of diodes connected to the coil from the intended blocking state to a conducting state, thereby turning the coil off (precluding reception), or possibly causing the amplifier to saturate.

Another category of problems is due to the fact that the coupling medium may itself produce a magnetic resonance signal. It may be unavoidable for the field of view of the magnetic resonance system to be chosen so as to include a signal produced by the coupling medium, in order to avoid signal “fold-in,” and this may in turn increase the scanning time, or may reduce the achievable image resolution. Moreover, if the medium exhibits a flow, this may cause an artifact in the reconstructed magnetic resonance images.

A number of techniques are known that address some of the problems noted above, but no technique is known that alleviates all of the above-cited problems.

Coupling media are known that do not produce contrast in a magnetic resonance image, such as oil, perfluorocarbon, etc. Assuming the medium that is employed does, in fact, not produce MR contrast, this approach may limit fold-in artifacts and flow artifacts. Such media, however, may still exhibit electrical loss and dielectric properties, which will define whether and how strongly the transmission and reception coils will couple to the medium. The use of such non-contrast-producing media, however, does not address the problem of coupling of the transmission coil to the RF active device, itself, and coupling between the RF active device to the magnetic resonance reception coil. Other factors that must be considered when choosing alternative liquids are cost, heat-carrying properties, ultrasound properties, aging properties, bio-compatibility and compatibility with other materials of the device.

Signal suppression techniques for magnetic resonance imaging are also known, such as saturation bands and flow suppression, which reduce the signal originating from the ultrasound coupling medium. Such techniques, however, have not proven to sufficiently suppress the signal, and moreover have an impact on the signal acquisition. Moreover, because saturation bands are executed with a large flip angle, this further increases the local specific absorption ratio and overall the risk of transducer's damage.

To alleviate the coupling between the electrical RF signal emitted by the device (e.g. ultrasound transducer, accelerometer, magnetometer, mechanical actuator, optical or infrared camera) and the reception coil, it is known to use blocking circuits that filter out unwanted signal contributions. Such blocking circuits are integrated into the reception coils, or their signal chain. This approach, therefore, requires the use of a specialized coil, and cannot be used in systems that are already fitted with conventional coils.

A further approach has been to synchronize the active RF device operation times so that magnetic resonance signal reception and “parasite” RF emission from that device do not occur simultaneously. This requires a synchronization circuit and architecture, and may limit the duty cycle of the ultrasound and/or of the magnetic resonance imaging. In the case of HIFU, for example, the available duty cycle is already significantly reduced when HIFU activation is interleaved with multi-slice magnetic resonance data acquisition. Using sequential acquisition of multiple slices enables a higher duty cycle of HIFU, but with the penalty of a lower signal-to-noise ratio in the magnetic resonance signal, and a lower temporal resolution. Moreover time-domain decoupling of sonication from MR acquisition does not provide any protection of the RF active device from thermal or electric damage.

### SUMMARY OF THE INVENTION

In accordance with the present invention, RF shielding is provided inside a magnetic resonance imaging or spectroscopy system, for an independent active device immersed in a coupling medium (such as an ultrasound transducer, accelerometer, magnetometer, mechanical actuator, optical or infrared camera) and/or for the coupling medium itself. The RF shielding is formed by an electrically conducting enclosure that has an open interior that is of appropriate size and shape, as well as at least a small region around the transducer at which “exposed” coupling medium might be present. The shield may be equipped with leads connected thereto allowing the shield to be placed at a suitable electrical potential but this option is not mandatory. Unlike classic RF shields which are evacuating the incident energy into the earth ground connection, here the electromagnetic energy deposited on the shield is damped into heat because of the polar molecules or ions surrounding the shield. Therefore the electromagnetic energy reaching the shield is not re-emitted, yielding minimal b1-artifacts in the region external to this shield. If there are free electrical charges (ions) in the surrounding water, the energy dissipation is faster. Even with the use of demineralized water, however, the water molecules are still highly polar and a small fraction of molecules is dissociated into OH⁻ and H₃0⁺ ions (pH=7), and are oscillating with the local electrical field so as to dissipate the energy in a sufficiently effective manner by dielectric coupling.

The open top of the shield housing is covered with an electrically conducting thin wire mesh that is electrically connected to shield housing. The bottom of the shield remains open in order to receive the RF active device. Alternatively, the shield is made from spare segments which can be assembled together around the RF active device.

By RF shielding the RF active device and the coupling medium, the problems noted above can be mitigated. The RF energy transmitted into the shield cavity is substantially reduced, so coupling from the magnetic resonance body coil to the ultrasound medium and to the transducer is correspondingly reduced. Conversely, radio-frequency energy is prevented from exiting from the interior of the shield cavity. Therefore, coupling to the magnetic resonance reception coil is also minimized. Moreover, the magnetic resonance signal originating from inside the shield cavity is reduced both by reducing the amount of signal excited by the transmission field and that received by the reception coil.

Because the shield is open at its top side, except for the aforementioned thin wire mesh, it is largely transparent to ultrasound transmission and propagation of infrared or visible light.

Finally, if a partial shielding effect is desired, for instance to enable magnetic resonance imaging of the shielded volume with attenuated RF excitation pulses (e.g. attenuated spin flip angle), it is further possible to adjust the design of the shield by adding supplementary openings covered by conductive wire mesh.

### BRIEF DESCRIPTION OF THE DRAWINGS

FIG. 1 is a perspective of an embodiment of an RF shield constructed in accordance with the present invention.

FIG. 2 is a plan view of the RF shield of FIG. 1.

FIG. 3 is a perspective view of a further embodiment of an RF shield in accordance with the present invention.

FIG. 4 schematically illustrates the RF shield in accordance with the invention immersed in a liquid.

### DESCRIPTION OF THE PREFERRED EMBODIMENTS

An RF shield 1 in accordance with the present invention is shown in FIGS. 1 and 2 and 4. As shown in FIG. 4, the RF shield 1 is immersed within water, saline solutions or other polar molecule liquids. The incident electromagnetic flux induces electrical currents in the shield, which are rapidly attenuated because of the electrical coupling between the RF shield 1 and its environment. The shield converts the electromagnetic incident energy into heat in the surrounding water. Because of this basic principle, the RF shield 1 cannot function solely in air, nor completely immersed in a non-polar insulator medium, such as oil.

The RF shield 1 has, in this embodiment, a generally cylindrical shield body 2 composed of electrically conductive material, such as copper, that has an interior cavity having a size and shape allowing an active RF device 4 to be placed therein. The interior cavity of the shield body 2 may also be large enough to encompass a small annular area around the transducer 4 at which “exposed” coupling medium may be located. The otherwise open top of the shield body 2 is covered by a wire mesh 3, that is also composed of electrically conductive material, and that is electrically connected to the shield body 2.

The shield body 2 has openings therein that allow cables 5 to proceed thereto for supplying power to the transducer in the interior cavity.

Optionally, the shield 1 may be provided with its own electrical leads 6 that may allow the entirety of the shield body and the wire mesh 3 to be placed at a selected electrical potential. Nevertheless, external wiring onto the shield is not a necessary condition for normal operating of the unit because the electromagnetic energy intercepted by the shield is damped into molecular agitation of the exposed medium.

Certain types of ultrasound transducers may be provided with a cooling system, in which water or some other coolant circulates beneath the ultrasound transducer. When the transducer and the RF shield 1 are used in the magnetic resonance system, the RF shield 1 blocks the magnetic resonance signal originating from the coolant (water) from producing flow artifacts in the resulting magnetic resonance image.

Although shown as a hollow cylinder in the embodiment of FIGS. 1 and 2 (and in the embodiment of FIG. 3 as well), the shield body 2 can be of any suitable shape, yet only be necessary that the size and shape of the interior cavity thereof are configured to receive and contain the type of transducer that is being shielded.

The further embodiment of an RF shield 1A is shown in FIG. 3. In this embodiment, the shield body 7 has a number of windows 8 therein so that the area inside the cavity of the shield 7 can still be made at least somewhat visible in the resulting magnetic resonance image, without significantly detracting from the shielding effect. Electrically conducting wires 9 can be provided around the circumference of the shield body 7, over the windows 8.

In this embodiment, since the material forming the shield body 7 is relatively thin, the presence of the windows 8 may reduce the mechanical stability of the overall shield, and thus a plastic insert 10 may be provided that surrounds the inner periphery of the shield body 7.

In each of the embodiments, in order to avoid eddy currents from the switched gradients that are used in magnetic resonance imaging, the RF shield can be segmented.

The wires of the mesh 3 preferably have an individual thickness that is less than or equal to approximately 10% of the wavelength of the ultrasound waves that are used.

The cables 5 that lead to the transducer 4 should themselves be individually shielded.

Although modifications and changes may be suggested by those skilled in the art, it is the intention of the inventors to embody within the patent warranted hereon all changes and modifications as reasonably and properly come within the scope of their contribution to the art.

We claim as our invention:

1. An MR-compatible radio-frequency (RF) shield immersed totally or partially within a liquid medium, for use with magnetic resonance system, comprising:
a shield body having an open interior cavity having a size and a shape configured to receive an active RF device, for instance but not limited to an ultrasound transducer therein that emits ultrasound, an accelerometer, an magnetometer, an mechanical actuator, an optical or infrared camera;
a thin wire mesh covering extending over a top of said shield body, through which said ultrasound, visible light or infrared light proceeds; and
said shield body and said covering each being comprised of electrically conductive material and being electrically connected with each other to form RF shielding that substantially encompasses said internal cavity.

2. An RF shield as claimed in claim 1 wherein the electromagnetic energy transferred into the shield is converted into thermal energy (or, heat) stored within the coupling medium surrounding the shield, without using any connection to an external ground plate.

3. An RF shield as claimed in claim 1 wherein said shield body comprises a plurality of circumferential openings therein.

4. An RF shield as claimed in claim 1 comprising electrically conductive wires circumferentially extending around said shield body over said openings.

5. An RF shield as claimed in claim 1 comprising a plastic insert in said interior cavity adjacent to an interior periphery of said shield body.

6. A method for shielding an ultrasound transducer or other RF active device used in a magnetic resonance system comprising the steps of:
immersing the ultrasound transducer or other RF active device within a liquid medium
operating an ultrasound transducer or other RF active device in a magnetic resonance system having at least one of an RF transmission coil and an RF reception coil; and
surrounding said ultrasound transducer or said other RF active device in said magnetic resonance system with RF shielding that substantially precludes coupling between said ultrasound transducer or said other active device and said at least one of said transmission coil and said reception coil.
